(19) United States
(12) Patent Application Publication
(10) Pub. No.: US 2005/0236653 A1
(43) Pub. Date: Oct. 27, 2005

(54) Image sensor having notch filter and method for fabricating the same

(76) Inventor: Youn-Sub Lim, Chungcheongbuk-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/073,344

(22) Filed: Mar. 4, 2005

(30) Foreign Application Priority Data
Apr. 23, 2004 (KR) 2004-28403

(51) Int. Cl. H01L 21/00; H01L 31/062

(52) U.S. Cl. 257/294; 438/70; 257/291; 257/432; 257/435

(57) ABSTRACT

Disclosed are an image sensor and a method for fabricating the same. The method includes the steps of: forming a plurality of photodiodes on a substrate; forming an insulation layer on the plurality of photodiodes; alternatively depositing an oxide layer and a nitride layer plural times on the insulation layer; forming a plurality of notch filters for blocking a green light by alternatively stacking the oxide layer and the nitride layer in a plurality of color filter regions of red and blue after selectively removing the oxide layer and the nitride layer stacked alternatively in the green color filter region; forming a planarization layer on the plurality of notch filters; and forming a plurality blue, green and red color filters on the plurality of notch filters.

### FIELD OF THE INVENTION

The present invention relates to a semiconductor device; and more particularly, to an image sensor and a method for fabricating the same capable of improving a color producing capability.

### DESCRIPTION OF RELATED ARTS

In general, an image sensor is a semiconductor device that converts an optical image into electrical signals. In the image sensor, a charge coupled device (CCD) is the semiconductor device that each of metal-oxide-silicon (MOS) capacitors are placed in close proximity and charge carriers are stored in or transferred to the capacitors. CMOS image sensors are devices adopting a switching method for detecting output sequentially by making and using as many MOS transistors as the number of pixels based on CMOS technology that uses peripheral circuits such as control circuits and signal processing circuits.

As for fabricating various image sensors, there are ongoing efforts to increase a photosensitivity of the image sensor and one of the efforts is a light collecting technology. For instance, the CMOS image sensor includes a photodiode that detects light and a CMOS logic circuit that converts the detected light into the electrical signals and makes a data. In order to increase the photosensitivity, there are efforts to increase a ratio which an area of the photodiode takes place out of an area of a total image sensor, i.e., a fill factor.

The image sensor has a color filter array (CFA) having three colors of blue (B), red (R) and green (G) and a color can be produced by mixing each of the colors. Hereinafter, the colors of blue, red and green are denoted as B, R and G, respectively.

A spectrum property of these color image sensors is directly influenced by a property of a color filter material and this spectrum property is reflected in the color producing property and capability. The spectrum property of a photoresist for a color filter that is now used does not show an ideal property. Also, there is a considerable overlap of each color, i.e., B, R and G and thus, a study related to tuning a filter thickness for increasing the photosensitivity should consider a problem caused by a degradation in the color producing property.

FIG. 1 is a cross-sectional view illustrating a conventional image sensor.

Referring to FIG. 1, a plurality of photodiodes 11 are placed on a substrate 10 and a first insulation layer 12, i.e., a planarization layer, is formed thereon. Next, a plurality of gate structures 13 are placed in regions which are not overlapped with the plurality of photodiodes 11, i.e., regions which are adjacent to the plurality of photodiodes 11. A plurality of light isolation layers 15 for isolating a light from entering to the plurality of gate structures 13 are placed on an upper portion of the plurality of gate structures 13. Herein, the plurality of light isolation layers 15 are overlapped with the plurality of gate structures 13. A second insulation layer 14, i.e., a pre metal dielectric (PMD) layer, is formed between the plurality of light isolation layers 15 and the plurality of gate structures 13. A third insulation layer, i.e., an over coating layer (OCL), is formed on the plurality of light isolation layers 15. Next, a plurality of color filters of blue (B), red (R) and green (G) 17A, 17B and 17C are placed, respectively on the third insulation layers 16 to overlap the plurality of photodiodes 11. Then, a fourth insulation layer 18, i.e., a planarization layer of the OCL, are placed on the plurality of color filters of B, R and G 17A, 17B and 17C. Afterwards, a plurality of microlenses 19 having a convex shape are placed on the fourth insulation layer 18 to respectively overlap the plurality of color filters of B, R and G 17A, 17B and 17C.

A color property of the image sensor described above is produced by using B, R and G color material layers. Thus, a filter property of each color of B, R and G is quite distant from an ideal cut-off property and spectrum regions of each color of B, R and G are basically overlapped with each other. Accordingly, these overlapped regions reduce a pure color component at a step of processing colors and influences on a ratio of a color signal to a noise, thereby inducing to reduce a dynamic range.

FIG. 2 is a graph illustrating a transmittance property, i.e., a spectrum property, in accordance with a wave length of each color of a conventional image sensor.

Referring to FIG. 2, the color of R has a high transmittancy in a wavelength area greater than approximately 600 nm. The color of G has a high transmittancy in a wavelength length ranging from approximately 500 nm to approximately 600 nm. The color of B has a high transmittancy in a wavelength area less than approximately 500 nm.

Meanwhile, even though a prominent wavelength area of the color of G ranges from approximately 500 nm to approximately 600 nm, the wavelength area of the color of G is widely distributed from approximately 450 nm to approximately 650 nm. Accordingly, a wide overlapping property of the color of G relatively decreases a ratio of the pure color component, thereby causing a problem in the color producing property.

Meanwhile, in case of decreasing a thickness of each color filter to increase a responding property of each color component there generates a problem in increasing a range of an overlap much more.

### SUMMARY OF THE INVENTION

It is, therefore, an object of the present invention to provide an image sensor and a method for fabricating the same capable of minimizing a region where a spectrum region of a color filter is overlapped, thereby improving a color producing property.

In accordance with one aspect of the present invention, there is provided an image sensor, including: a plurality of photodiodes formed on a substrate; a plurality of blue, green and red color filters on an upper portion of the plurality of photodiodes; and a plurality of notch filters formed on lower portions of the red and blue color filters blocking a green light in the regions of the red and blue color filters.

In accordance with anther aspect of the present invention, there is provided a method for fabricating the image sensor, including the steps of: forming a plurality of photodiodes on a substrate; forming an insulation layer on the plurality of photodiodes; alternatively depositing an oxide layer and a nitride layer plural times on the insulation layer; forming a plurality of notch filters for blocking a green light by alternatively stacking the oxide layer and the nitride layer in a plurality of color filter regions of red and blue after selectively removing the oxide layer and the nitride layer stacked alternatively in the green color filter region; forming a planarization layer on the plurality of notch filters; and forming a plurality blue, green and red color filters on the plurality of notch filters.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a cross-sectional view illustrating a conventional image sensor;

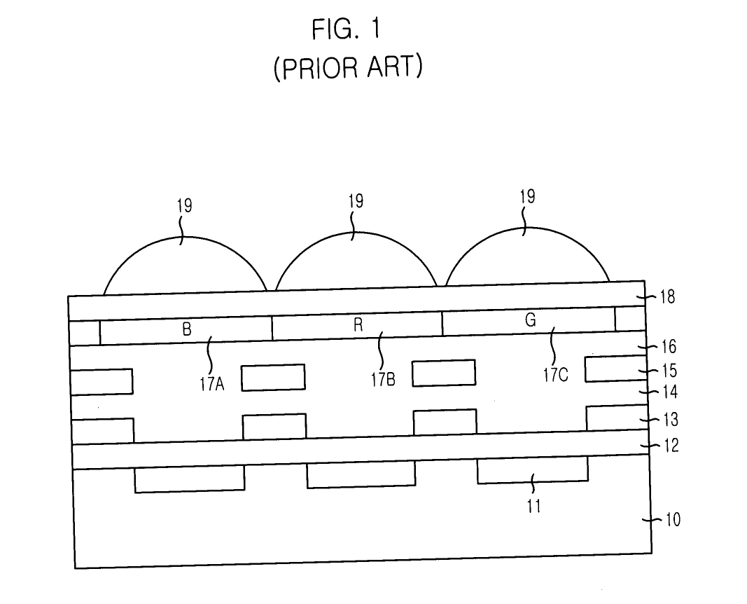

FIG. 2 is a graph illustrating a transmittance property, i.e., a spectrum property, in accordance with a wavelength of each color of a conventional image sensor;

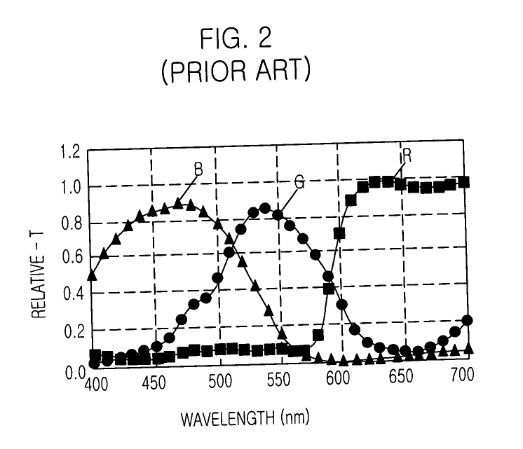

FIG. 3 is a cross-sectional view illustrating an image sensor in accordance with the present invention;

FIG. 4 is a cross-sectional view illustrating a notch filter having a multi layer structure of an image sensor in accordance with the present invention;

FIG. 5 is a graph illustrating a spectrum property of a notch filter in accordance with the present invention;

FIG. 6 is a graph illustrating a spectrum property of an image sensor in accordance with the present invention; and

FIGS. 7A to 7C are cross-sectional views illustrating a process for fabricating an image sensor having a plurality of notch filters in accordance with the present invention.

### DETAILED DESCRIPTION OF THE INVENTION

Hereinafter, detailed descriptions on preferred embodiments of the present invention will be provided with reference to the accompanying drawings.

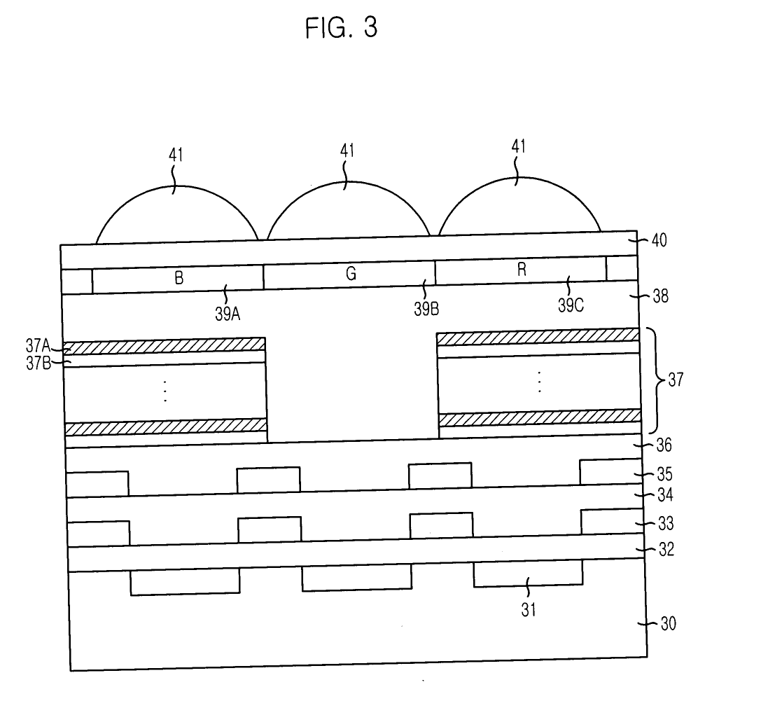

FIG. 3 is a cross-sectional view illustrating an image sensor in accordance with the embodiments of the present invention.

Referring to FIG. 3, an image sensor in accordance with the present invention includes a substrate 30, a plurality of photodiodes 31, a first insulation layer 32, a plurality of gate structures 33, a second insulation layer 34, a photo isolation layer 35, a third insulation layer 36, a plurality of notch filters 37, a fourth insulation layer 38, a plurality of color filters of blue (B), green (G) and red (R) 39A, 39B and 39C, a fifth insulation layer 40 and a plurality of microlenses 41.

The plurality of photodiodes 31 are placed on the substrate 30. Next, the first insulation layer 32 is formed thereon and then, the plurality of gate structures 33 are formed on regions which are not overlapped with the plurality of photodiodes 31 on the first insulation layer, i.e., regions which are adjacent to the plurality of photodiodes 31. Next, the second insulation layer 34 is formed on the plurality of gate structures 33 and then, the photo isolation layer 35 is formed on the second insulation layer 34 in order to overlap the plurality of gate structures 33 for blocking an entrance of light. The third insulation layer 36 is formed on the photo isolation layer 35 and then, the plurality of notch filters 37 serving a role in blocking a green light in a plurality of color filter areas of R and B is formed on the plurality of color filters of R and B. Next, the fourth insulation layer 38 is formed on the plurality of notch filters 37 and the plurality of color filters of B, G and R 39A, 39B and 39C are formed thereon. Afterwards, the fifth insulation layer 40, i.e. a planarization layer, is formed on the plurality of color filters of B, G and R 39A, 39B and 39C. Finally, a plurality of microlenses 41 are placed on the fifth insulation layer 40 in order to respectively overlap the plurality of color filters of B, G and R 39A, 39B and 39C, thereby completing a image sensor formation.

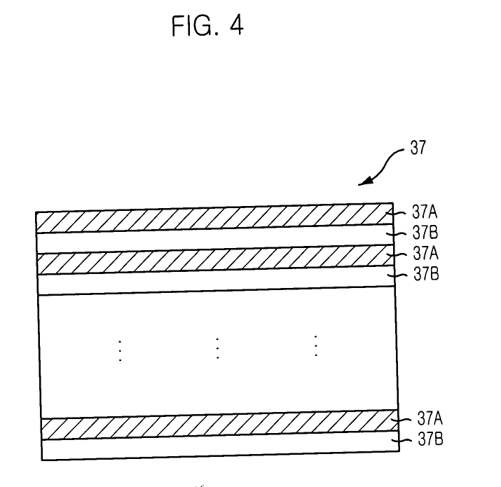

FIG. 4 is a cross-sectional view illustrating a notch filter having a multi layer structure in accordance with the present invention.

The notch filter 37 has a characteristic of blocking a light having a special wavelength. Referring to FIG. 4, the notch filter 37 is formed by alternatively depositing a nitride layer 37A and an oxide layer 37B, thereby having a bi-layer structure. It is preferable that the nitride layer 37A and the oxide layer 37B should be repeatedly stacked at least ten times to form the notch filter 37.

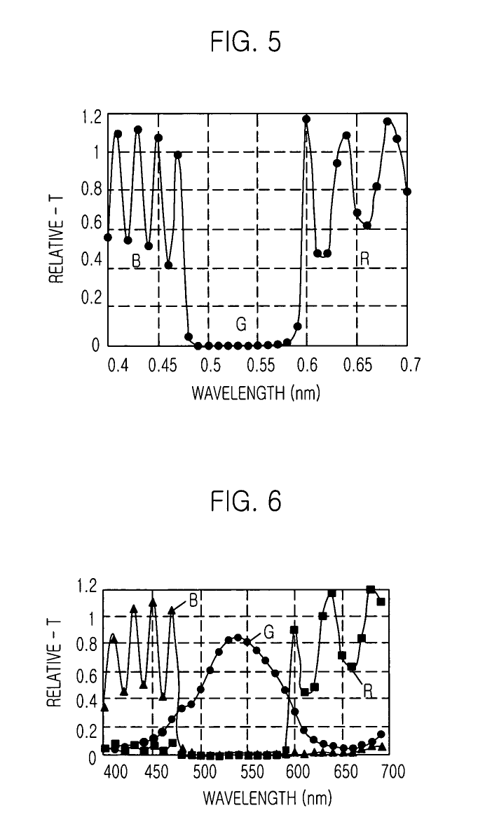

FIG. 5 is a graph illustrating a spectrum property of the notch filter in accordance with the present invention. Referring to FIG. 5, the notch filter is formed by stacking the nitride layer 37A of which an index of refraction ranges from approximately 1.96 to approximately 2.01 and the oxide layer 37B of which an index of refraction ranges from approximately 1.45 to approximately 1.488. Accordingly, the notch filter 37 is a quarter wavelength reflector stack (QWRS) of a standard wavelength of a 0.5 μm having a spectrum property mostly blocking a green light with an amount ranging from approximately 0.5 μm, i.e., approximately 500 nm, to approximately 0.6 μm, i.e., approximately 600 nm. It is preferable that the nitride layer 37A has a thickness ranging from approximately 800 Å to approximately 1,000 Å and the oxide layer 37B has a thickness ranging from approximately 600 Å to approximately 700 Å.

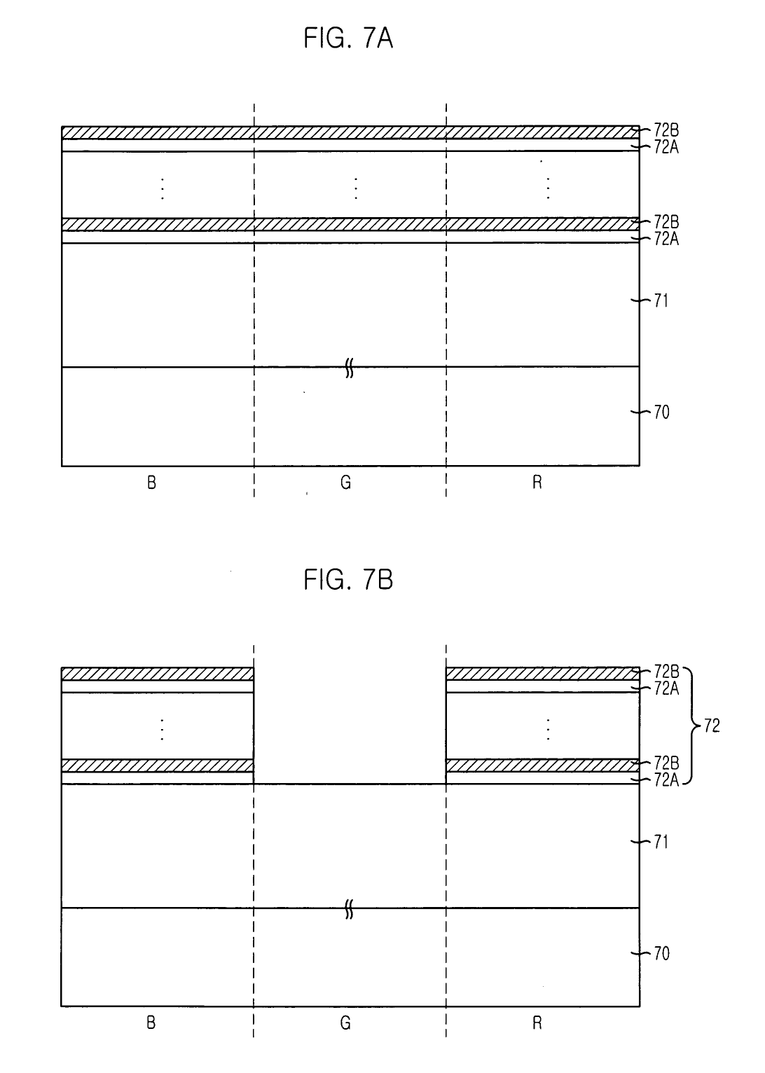

FIG. 6 is a graph illustrating a spectrum property of an image sensor in accordance with the present invention.

Referring to FIG. 6, a component of the color of G is mostly removed in the plurality of color regions of B and R and the component of the color of G hardly influences on the colors of B and R. Accordingly, the spectrum property is improved, thereby minimizing overlapping areas between spectrum areas of G and B.

Meanwhile, although the present invention exemplifies the plurality of microlenses having a convex shape, it is possible to use a plurality of microlenses having a concave shape in accordance with the present invention.

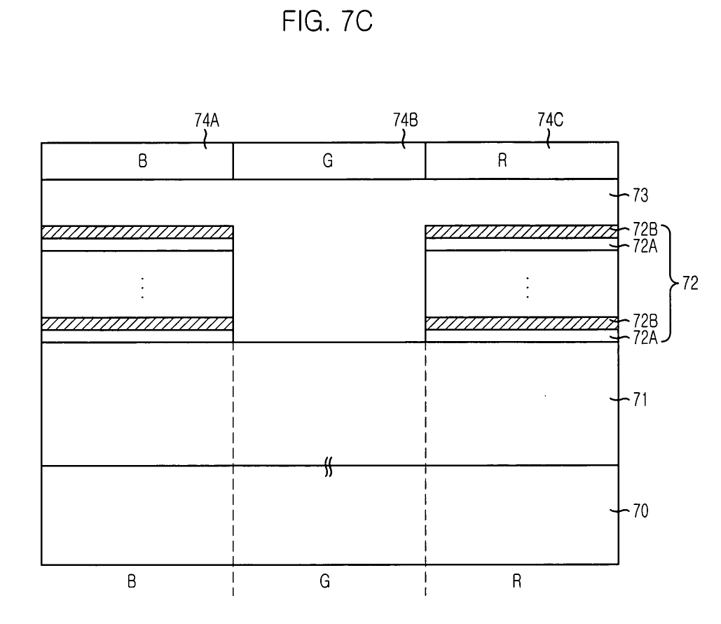

FIGS. 7A to 7C are cross-sectional views illustrating an image sensor having a notch filter in accordance with the embodiments of the present invention.

Referring to FIG. 7A, a photodiode (not shown) and a transistor are formed on a substrate 70 which is divided into a plurality of regions where a plurality of color filters of B, G and R will be formed. Then, an insulation layer 71 is formed thereon.

Afterwards, a gate structure and a photo isolation layer are formed; however, detailed processes for forming these constitution elements are omitted.

Subsequently, an oxide layer 72A and a nitride layer 72B are alternatively deposited on the insulation layer 71 with repeated times, thereby forming a bi-layer structure of the oxide layer 72A and the nitride layer 72B.

At this time, the oxide layer 72A and the nitride layer 72B are repeatedly stacked more than approximately 10 times and both of the oxide layer 72A and the nitride layer 72B should have a thickness ranging from approximately 800 Å to approximately 1,000 Å. Accordingly, the oxide layer having an index of refraction ranging from approximately 1.45 to approximately 1.488 and the nitride layer 72B having an index of refraction ranging from approximately 1.96 to approximately 2.01 are stacked, thereby forming a plurality of notch filters. Herein, the plurality of notch filters become the QWRS of the standard wavelength of approximately 0.5 μm having the spectrum property which mostly blocks the green light with an amount ranging from approximately 0.5 μm, i.e., approximately 500 nm, to approximately 0.6 μm, i.e., approximately 600 nm.

Referring to FIG. 7B, a photoresist pattern for removing the oxide layer 72A and the nitride layer 72B alternatively stacked is formed in the color region of C and then, the oxide layer 72A and the nitride layer 72B alternatively stacked are removed in the color region of R by using the photoresist pattern as an etch mask, thereby forming the plurality of notch filters 72 having a bi-layer structure of the oxide layer 72A and the nitride layer 72B in the color regions of B and R.

Referring to FIG. 7C, the photoresist pattern is removed, and then, a planarization layer 73, i.e., an over coating layer (OCL), is formed. Afterwards, a plurality of color filters of B, G and R 74A, 74B and 74C are formed on an upper portion of the planarization layer 73 by using a typical process.

Meanwhile, even though not illustrated, a process for forming the image sensor is completed by additionally employing processes for forming a planarization layer, a plurality of microlenses and a passivation layer on the plurality of color filters of B, G and R 74A, 74B and 74C.

The present invention described in the above forms a filter having a multi-layer structure on a lower portion of a plurality of color filters of B and R in case of improving a color producing property as normally using a photoresist pattern for a basic color filter, thereby forming a plurality of notch filters filtering and removing colors of G and cyan (Cy) in a plurality of color regions of B and R. Accordingly, the present invention limits a correspondence of a color of B or R distributed to an existing color region of G to only itself, thereby increasing a ratio of pure signal composition and then, improving a color producing capability of an image sensor.

The present invention can improve a color producing capability of an image sensor, thereby providing an outstanding effect of fundamentally improving a capability of an image sensor.

The present application contains subject matter related to the Korean patent application No. KR 2004-0028403, filed in the Korean Patent Office on Apr. 23, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. An image sensor, comprising:
a plurality of photodiodes formed on a substrate;
a plurality of blue, green and red color filters on an upper portion of the plurality of photodiodes; and
a plurality of notch filters formed on lower portions of the red and blue color filters blocking a green light in the regions of the red and blue color filters.

2. The method of claim 1, wherein the plurality of notch filters include a structure formed by alternatively stacking a nitride layer and an oxide layer.

3. The method of claim 2, wherein the plurality of notch filters are formed by alternatively stacking a nitride layer and an oxide layer at least 10 times.

4. The method of claim 2, wherein an index of refraction of the nitride layer ranges from approximately 1.96 to approximately 2.01 and an index of refraction of the oxide layer ranges from approximately 1.45 to approximately 1.488.

5. The method of claim 2, wherein a thickness of the nitride layer ranges from approximately 800 Å to approximately 1,000 Å and a thickness of the oxide layer ranges from approximately 600 Å to approximately 700 Å.

6. The method of claim 1, wherein further includes a plurality of microlenses placed on each of the plurality of color filters.

7. The method of claim 6, wherein further including the plurality of microlenses having a convex or concave shape.

8. A method for forming an image sensor, comprising the steps of:
forming a plurality of photodiodes on a substrate;
forming an insulation layer on the plurality of photodiodes;
alternatively depositing an oxide layer and a nitride layer plural times on the insulation layer;
forming a plurality of notch filters for blocking a green light by alternatively stacking the oxide layer and the nitride layer in a plurality of color filter regions of red and blue after selectively removing the oxide layer and the nitride layer stacked alternatively in the green color filter region;
forming a planarization layer on the plurality of notch filters; and
forming a plurality blue, green and red color filters on the plurality of notch filters.

9. The method of claim 8, wherein the plurality of notch filters are formed by alternatively stacking a nitride layer and an oxide layer at least 10 times.

10. The method of claim 9, wherein the nitride layer has a thickness ranging from approximately 800 Å to approximately 1,000 Å and the oxide layer has a thickness ranging from approximately 600 Å to approximately 700 Å.

11. The method of claim 8, wherein further including a step of forming a plurality of microlenses on the plurality of color filters after the step of forming the plurality of blue, green and red color filters.
